(19) United States
(12) Patent Application Publication
(10) Pub. No.: US 2007/0205516 A1
(43) Pub. Date: Sep. 6, 2007

(54) Low-k dielectric layer, semiconductor device, and method for fabricating the same

(75) Inventors: Kei-Wei Chen, Taipei (TW); Sheng-Wen Chen, Taipei (TW); Shiu-Ko Jangjian, Kaohsiung (TW); Shih-Ho Lin, Hsinchu (TW); Hung-Jui Chang, Changhua (TW); Yu-Ku Lin, Hsinchu (TW); Ying-Lang Wang, Taichung (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/364,088

(22) Filed: Mar. 1, 2006

(51) Int. Cl. H01L 23/48; H01L 23/52; H01L 29/40

(52) U.S. Cl. 257/760

(57) ABSTRACT

Low-k dielectric layer, semiconductor device, and method for fabricating the same. The low-k dielectric layer comprises a hardened sub-layer sandwiched by two low-k dielectric sub-layers. The hardened sub-layer is formed by a method comprising bombarding the underlying low-k dielectric sub-layer utilizing hydrogen plasma or inert gas plasma. The semiconductor device comprises the low-k dielectric layer overlying an etch stop layer overlying a substrate, and a conductive material embedded in the dielectric layer and the etch stop layer, electrically connecting to the substrate.

### BACKGROUND

The invention relates to semiconductor technology, and more specifically to a dielectric layer utilized in a semiconductor device.

In the back end of semiconductor chip fabricating processes, the metal systems necessary to connect the devices and different layers are added to the chip by a process called metallization, comprising forming a dielectric layer over a semiconductor substrate, planarizing and patterning the dielectric layer to form trenches and/or vias, and filling the trenches and/or vias to forming conducting wires and/or via plugs. A chemical mechanical polishing process is then performed to planarize the surface of the semiconductor substrate.

Development of a smaller, more powerful semiconductor chip with denser electronic device and interconnect populations is desirable. Parasitic capacitance, however, between the metal interconnects, which leads to RC delay and crosstalk, increases correspondingly. Therefore, to reduce the parasitic capacitance, increasing the speed of conduction between the metal interconnections, a low-k dielectric material is commonly employed to form an inter-layer dielectric (ILD) layer.

The low-k dielectric material has lower strength, and thus, is potentially deformed due to stress induced by subsequent process and/or thermal cycling. For example, the low-k dielectric material is typically deformed due to stress induced by encapsulant flows during an underfill step in a flip-chip packaging process, potentially peeling the metal interconnections off the ILD layer, resulting in open circuitry, thereby negatively affecting yield and reliability of the semiconductor device.

In U.S. Pat. No. 6,924,242, Jang et. al. describe a dielectric layer comprising one or more dielectric sub-layers and one and more respective hardened sub-layers upon the dielectric sub-layers. The hardened sub-layers are formed by performing a hydrogen plasma treatment on the dielectric sub-layers. The hydrogen plasma treatment, however, potentially increases the dielectric constant (k) of the dielectric layer. Jang et. al. describe neither a structure nor a method of preventing the increase in dielectric constant of the dielectric layer.

### SUMMARY

Thus, the invention provides a low-k dielectric layer, semiconductor device, and method for fabricating the same, strengthening the dielectric layer, thereby preventing delamination of ILD layers utilizing a low k material on the chip to improve yield and reliability of the semiconductor device.

The invention provides a low-k dielectric layer. The low-k dielectric layer includes a hardened sub-layer sandwiched by two low-k dielectric sub-layers.

The invention further provides a semiconductor device. The semiconductor device includes a substrate, an etch stop layer, a low-k dielectric layer, and a conductive material. The etch stop layer overlies an active surface of the substrate. The low-k dielectric layer overlies the etch stop layer. The low-k dielectric layer comprises a hardened sub-layer sandwiched by two low-k dielectric sub-layers. The conductive material is embedded in the low-k dielectric layer and etch stop layer, and thus, electrically connects the substrate.

The invention further provides a method for fabricating a semiconductor device. First, a substrate is provided. The substrate comprises an etch stop layer on a surface. Next, a first low-k dielectric sub-layer is formed overlying the etch stop layer by CVD. Next, a hardened sub-layer is formed overlying the first low-k dielectric sub-layer by bombardment of a surface of the first low-k dielectric sub-layer utilizing hydrogen plasma or inert gas plasma, and thus, a repeating structure, comprising the first low-k dielectric sub-layer and the overlying hardened sub-layer, is formed. Further, an uppermost low-k dielectric sub-layer is formed overlying the hardened sub-layer utilizing CVD, and thus, a low-k dielectric layer, comprising the uppermost low-k dielectric sub-layer and the repeating structure, is formed. Finally, a conductive material is embedded in the low-k dielectric layer and etch stop layer. The conductive material electrically connects the substrate.

Further scope of the applicability of the invention will become apparent from the detailed description given hereinafter. It should be understood, however, that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The invention can be more fully understood by reading the subsequent detailed description in conjunction with the examples and references made to the accompanying drawings, which are given by way of illustration only, and thus are not limitative of the invention, and wherein:

FIG. 1A is a cross-section of a low-k dielectric layer of an embodiment of the invention.

FIG. 1B is a cross-section of a low-k dielectric layer of an embodiment of the invention.

FIG. 2 is a cross-section of a semiconductor device of an embodiment of the invention.

FIGS. 3A through 3E are cross-sections of a method for fabricating a semiconductor device of an embodiment of the invention.

### DESCRIPTION

The following embodiments are intended to illustrate the invention more fully without limiting the scope of the claims, since numerous modifications and variations will be apparent to those skilled in this art.

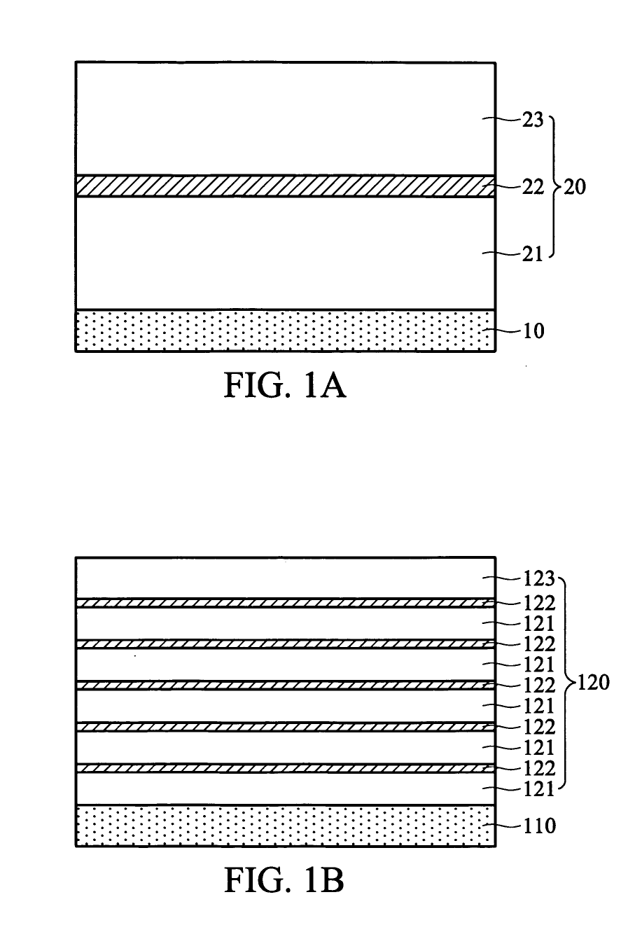

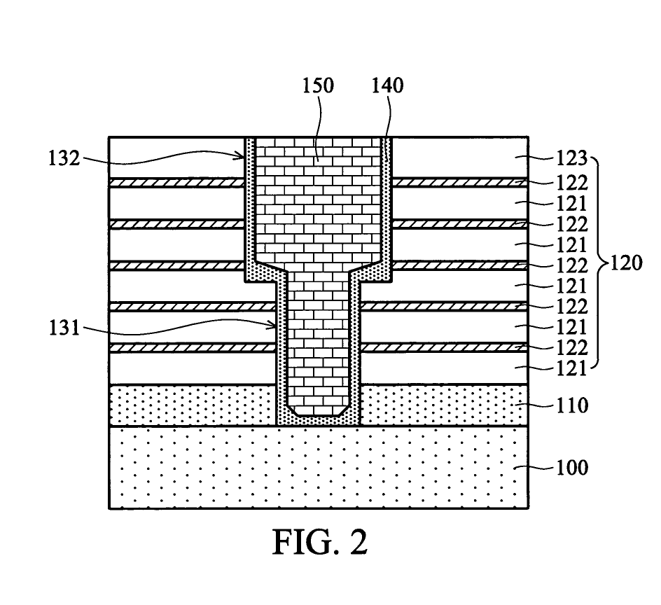

FIG. 1A shows a low-k dielectric layer 20 of an embodiment of the invention. The low-k dielectric layer 20 can be disposed on a base material such as an etch stop layer 10, i.e. SiC, SiCO, SiCN, combinations thereof, or other insulating materials. A low-k dielectric layer 20 comprises a hardened sub-layer 22 sandwiched by two low-k dielectric sub-layers 21 and 23. The low-k dielectric sub-layers 21 and 23, as the name indicates, have dielectric constants less than 4, and preferably less than 3, such as carbon containing dielectric, i.e. Black-diamond, SILK, CORAL, DEMS (diethoxymethylsilane), 3MS (trimethylsilane), a combination thereof, or other carbon containing dielectrics. The low-k dielectric sub-layers 21 and 23 can be other known substantially carbon-free dielectrics.

The hardened sub-layer 22 is preferably formed by bombarding the underlying low-k dielectric sub-layers 21 utilizing hydrogen plasma or inert gas plasma, such as helium, argon, a combination thereof, or other inert gases. The hardened sub-layer 22 has better physical properties, such as higher density, higher hardness, and/or higher strength than the low-k dielectric sub-layers 21 and 23. In some cases, for example, the hardness of the low-k dielectric sub-layers 21 and 23 is between about 0.1 and about 49 GPa while that of the hardened sub-layer 22 is between about 0.5 and 50 GPa. Thus, the low-k dielectric layer 20 acts as a composite material comprising stronger hardened sub-layer 22 and weaker but flexible low-k dielectric sub-layers 21 and 23 to be more resistant to stress induced by thermal cycling and/or other environmental factors. When utilizing the low-k dielectric layer 20 in a semiconductor device as an ILD layer, for example, residual metal interconnection peelings from the ILD layer resulting from deformation of the ILD layer is substantially reduced or completely prevented, improving yield and reliability of the semiconductor device.

The hardened sub-layer 22 is preferably between 5 and 10% as thick as the low-k dielectric layer 20, and thus, the total dielectric constant (k value) of the low-k dielectric layer 20 is not substantially negatively affected, i.e. increased, for denser electronic device and interconnect populations. When the hardened sub-layer 22 is thinner than 5% of the low-k dielectric layer 20, improvement in the ILD deformation may be limited. When the hardened sub-layer 22 is thicker than 10% of the low-k dielectric layer 20, k value of the low-k dielectric layer 20 may substantially be negatively affected, i.e. increased.

In one embodiment, the hardened sub-layer 22 is as thick as approximately 10 Å. In some embodiments, the hardened sub-layer 22 is as thick as approximately 500 Å or less, and is preferably as thick as approximately 250 Å or less.

In FIG. 1B, a low-k dielectric layer 120 of another embodiment of the invention is shown. The low-k dielectric layer 120 can be disposed on a base material such as an etch stop layer 110, i.e. SiC, SiCO, SiCN, combinations thereof, or other insulating materials. The low-k dielectric layer 120 comprises a hardened sub-layer 122 sandwiched by a first low-k dielectric sub-layer 121 and an uppermost low-k dielectric sub-layer 123. The low-k dielectric layer 120 may further comprise a repeating structure comprising the hardened sub-layer 122 and the overlying or underlying first low-k dielectric sub-layers 121. The low-k dielectric layer 120 may further comprise a plurality of the repeating structures.

As the low-k dielectric layer 20, the low-k dielectric layer 120 is more resistant to stress induced by thermal cycling and/or other environmental factors.

In an embodiment, the total thickness of the hardened sub-layers 122 is preferably between 5 and 10% of a thickness of the low-k dielectric layer 120. In another embodiment, a ratio of counts of the low-k dielectric sub-layers 121 and 123 to the hardened sub-layers 122 is greater than 1. Thus, the total k value of the low-k dielectric layer 120 is not substantially negatively affected, i.e. increased, for higher density electronic device and interconnect populations.

When the total thickness of the hardened sub-layers 122 is less than 5% of the thickness of the low-k dielectric layer 120, improvement in the ILD deformation may be limited. When the total thickness of the hardened sub-layers 122 is larger than 10% of the thickness of the low-k dielectric layer 120, k value of the low-k dielectric layer 120 may substantially be negatively affected, i.e. increased.

In one embodiment, the hardened sub-layer 122 is as thick as approximately 10 Å. In some embodiments, the hardened sub-layer 122 is as thick as approximately 500 Å or less, and is preferably as thick as approximately 250 Å or less.

Further, other details regarding the low-k dielectric sub-layers 121 and 123, hardened sub-layers 122, and low-k dielectric layer 120 are respectively the same as the described low-k dielectric sub-layers 21 and 23, hardened sub-layers 22, and low-k dielectric layer 20, and thus, are omitted herefrom.

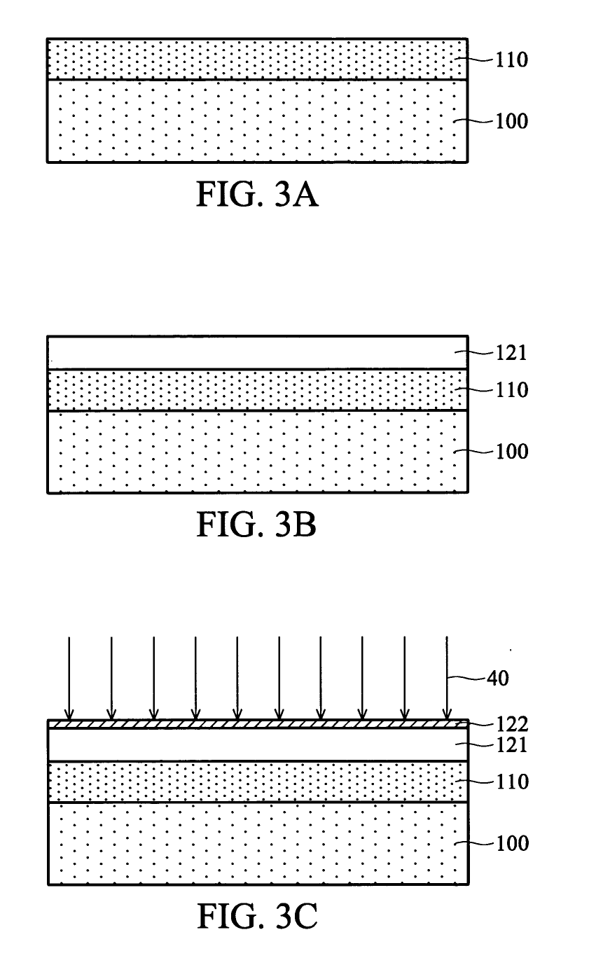

FIG. 2 is an embodiment of a semiconductor device. The semiconductor device comprises a substrate 100 comprising the described etch stop layer 110 on a surface, the described low-k dielectric layer 120, and a conductive material embedded in the low-k dielectric layer 120. The semiconductor device may comprise the low-k dielectric layer 20 instead of the layer 120 as desired.

The substrate 100 is semiconductor material such as silicon, germanium, a combination thereof, compound semiconductor materials, or others. The etch stop layer 110 protects the underlying substrate 100 during the patterning or etching of the low-k dielectric layer 120, and also provides improved adhesion for subsequently formed low-k dielectric layer 120. Details regarding the etch stop layer 110 and low-k dielectric layer 120 are respectively the same as the described, and thus, are omitted herefrom.

The conductive material acts as a plug, a wiring layer, a combination thereof, or other applications in the semiconductor device. The conductive material preferably electrically connects to the substrate 100. In a preferred embodiment, the conductive material comprises a main portion 150 and a conformal barrier layer 140 between the low-k dielectric layer 120 and the main portion 150. The main portion 150 preferably comprises doped polycrystalline silicon, tungsten, copper, aluminum, conductive metal compounds, a combination thereof, or other conductive materials. The barrier layer 140 preferably comprises metal nitride to prevent inter-diffusion between the low-k dielectric layer 120 and the main portion 150. In an embodiment, the main portion 150 comprises copper and the barrier layer 140 comprises tantalum nitride.

In a conventional semiconductor device comprising an ILD layer consisting of substantially the same material as the first low-k dielectric sub-layers 121, the k value of the ILD layer is approximately 2.96 and etch rate of the ILD layer is approximately 2654 Å/min. In one embodiment of the semiconductor device comprising the low-k dielectric layer 120 as an ILD layer, the k value of the low-k dielectric layer 120 is also approximately 2.96 and etch rate of the low-k dielectric layer 120 is approximately 2418 Å/min. As described, the low-k dielectric layer 120 is more resistant to stress induced by thermal cycling and/or other environmental factors. Thus, deformation of the low-k dielectric layer 120 and peel-off of the main portion 150 and barrier layer 140 induced thereby can be reduced or prevented without increasing the k value of the layer 120, improving the yield and reliability of the semiconductor device.

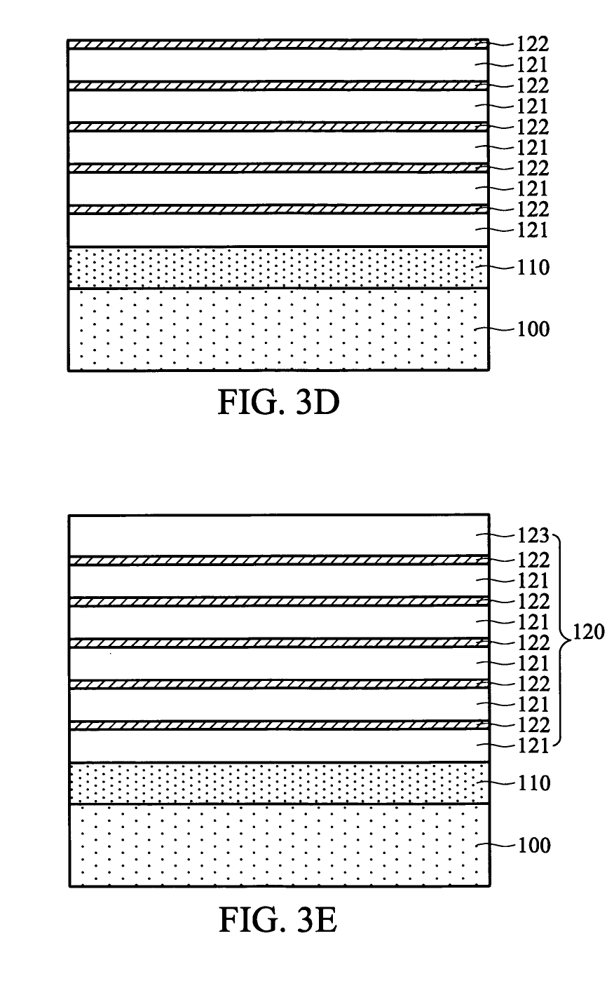

FIGS. 3A through 3E are cross-sections of an embodiment of a method for fabricating a semiconductor device.

FIG. 3A shows a substrate 100, comprising an etch stop layer 110 as described on a surface. The etch stop layer 110 may be previously formed by a method such as chemical vapor deposition (CVD).

FIG. 3B shows a first low-k dielectric sub-layer 121, as described, formed overlying the etch stop layer 110 by a method such as CVD, spin-on, or other known film forming methods. In FIG. 3C, a plasma bombardment procedure is performed on a surface of the first low-k dielectric sub-layer 121 by plasma 40 to form the described hardened sub-layer 122. The plasma bombardment procedure can be performed in-situ or ex-situ. When the first low-k dielectric sub-layer 121 is form by CVD, the hardened sub-layer 122 is preferably formed in-situ in the same chamber. The plasma 40 is preferably hydrogen or inert gas such as helium, argon, a combination thereof, or other inert gases.

Optionally, the steps shown in FIGS. 3B and 3C can be repeated to form one or more repeating structures comprising the first low-k dielectric sub-layer 121 and hardened sub-layer 122. An exemplary embodiment is shown in FIG. 3D.

The conditions of plasma 40 in the step of FIG. 3C and/or repeating formation of the hardened sub-layers 122 of FIG. 3D are preferably controlled to prevent substantial increase of k value and provide substantial improvement of physical properties, such as higher density, higher hardness, and/or higher strength, for the subsequently completed low-k dielectric layer 120. When plasma 40 is hydrogen, the preferred conditions comprise:

H₂ flow: from about 10 to 500 sccm and more preferably from about 50 to 250 sccm;

temperature: preferably from room temperature to about 200° C. and more preferably from room temperature to about 100° C.;

pressure: preferably from about 5 to 200 mTorr and more preferably from about 5 to 100 mTorr;

time: preferably from about 5 to 200 seconds and more preferably from about 5 to 100 seconds; and

power: preferably from about 1 to 100 W and more preferably from about 1 to 50 W.

When plasma 40 is helium, the preferred conditions comprise:

He flow: from about 10 to 500 sccm and more preferably from about 50 to 250 sccm;

temperature: preferably from (room temperature) to about 200° C. and more preferably from room temperature to about 100° C.;

pressure: preferably from about 5 to 200 mTorr and more preferably from about 5 to 100 mTorr;

time: preferably from about 5 to 200 seconds and more preferably from about 5 to 100 seconds; and

power: preferably from about 1 to 100 W and more preferably from about 1 to 50 W.

When plasma 40 is argon, the preferred conditions comprise:

Ar flow: from about 10 to 500 sccm and more preferably from about 50 to 250 sccm;

temperature: preferably from room temperature to about 200° C. and more preferably from room temperature to about 100° C.;

pressure: preferably from about 5 to 100 mTorr and more preferably from about 5 to 50 mTorr;

time: preferably from about 5 to 200 seconds and more preferably from about 5 to 100 seconds; and

power:. preferably from about 1 to 100 W and more preferably from about 1 to 50 W.

When plasma 40 is a combination of helium and argon, the preferred conditions comprise:

He flow: from about 5 to 500 sccm and more preferably from about 10 to 250 sccm;

Ar flow: from about 5 to 500 sccm and more preferably from about 10 to 250 sccm;

total flow of He and Ar: from about 10 to 500 sccm and more preferably from about 10 to 250 sccm;

temperature: preferably from room temperature to about 200° C. and more preferably from room temperature to about 100° C.;

pressure: preferably from about 5 to 100 mTorr and more preferably from about 5 to 100 mTorr;

time: preferably from about 5 to 200 seconds and more preferably from about 5 to 100 seconds; and

power: preferably from about 1 to 100 W and more preferably from about 1 to 50 W.

In FIG. 3E, an uppermost low-k dielectric sub-layer 123 is in-situ or ex-situ formed overlying the hardened sub-layer 122 by a method such as CVD, spin-on, or other known film forming methods, and preferably in-situ formed by CVD. Thus, the low-k dielectric layer 120 is completed. When the low-k dielectric layer 120 comprises only one low-k dielectric sub-layer 121 and the overlying hardened sub-layer 122, and the uppermost low-k dielectric sub-layer 123, the low-k dielectric layer is equivalent to the described layer 20. In this embodiment, the low-k dielectric layer 120 comprises a plurality of the repeating structures respectively comprising the low-k dielectric sub-layer 121 and the overlying hardened sub-layer 122, and the uppermost low-k dielectric sub-layer 123.

In an embodiment, total thickness of the hardened sub-layers 122 are preferably between 5 and 10% of a thickness of the low-k dielectric layer 120. In another embodiment, the ratio of counts of deposition of the low-k dielectric sub-layers 121 and 123 to the plasma bombardment procedures is greater than 1. Thus, the total k value of the low-k dielectric layer 120 is not substantially negatively affected, i.e. increased, for denser electronic device and interconnect populations.

Finally, the described conductive material is embedded in the low-k dielectric layer 120 and etch stop layer 110, and preferably electrically connects to the substrate 100. In a preferred embodiment, a damascene process is performed. In an exemplary procedure, the low-k dielectric layer 120 and etch stop layer 110 is patterned to form a via 131 and an above trench 132 therethrough, followed by sequential formation of a barrier layer 140 and a main portion 150. The barrier layer 140, conformally on the bottom and sidewalls of the via 131 and trench 132, is formed by a method such as CVD. The main portion 150 overlying the barrier layer 140 is formed by a method such as CVD, electroplating, electroless plating, sputtering, evaporation, or other known methods. Further, an additional chemical mechanical polishing (CMP) is preferably performed to planarize the conductive material and low-k dielectric layer 120. Thus, the semiconductor device as shown in FIG. 2 is completed.

While the invention has been described by way of example and in terms of preferred embodiment, it is to be understood that the invention is not limited thereto. It is therefore intended that the following claims be interpreted as covering all such alteration and modifications as fall within the true spirit and scope of the invention.

What is claimed is:

1. A low-k dielectric layer, comprising:
a hardened sub-layer, between 5 and 10% as thick as the low-k dielectric layer, sandwiched by two low-k dielectric sub-layers.

2. The layer as claimed in claim 1, further comprising a repeating structure comprising the hardened sub-layer and the overlying or underlying low-k dielectric sub-layer.

3. The layer as claimed in claim 1, wherein the hardness of the low-k dielectric sub-layers is between about 0.1 and about 49 GPa while that of the hardened sub-layer is between about 0.5 and about 50 GPa.

4. The layer as claimed in claim 2, wherein total thickness of the hardened sub-layers is between 5 to 10% of a thickness of the low-k dielectric layer.

5. The layer as claimed in claim 2, wherein a ratio of counts of the low-k dielectric sub-layers to the hardened sub-layers is greater than 1.

6. The layer as claimed in claim 1, wherein the low-k dielectric sub-layers comprise carbon.

7. The layer as claimed in claim 1, wherein the low-k dielectric sub-layers are Black-diamond, SILK, CORAL, DEMS (diethoxymethylsilane), 3MS (trimethylsilane), or a combination thereof.

8. The layer as claimed in claim 1, wherein the hardened sub-layer is the underlying low-k dielectric sub-layer bombarded by hydrogen plasma or inert gas plasma.

9. The layer as claimed in claim 8, wherein the inert gas comprises helium, argon, or a combination thereof.

10. A semiconductor device, comprising:
a substrate comprising an etch stop layer on a surface;
a low-k dielectric layer, comprising a hardened sub-layer, between 5 and 10% as thick as the low-k dielectric layer, sandwiched by two low-k dielectric sub-layers, overlying the etch stop layer; and
a conductive material embedded in the low-k dielectric layer and etch stop layer, electrically connecting the substrate.

11. The device as claimed in claim 10, wherein the low-k dielectric layer further comprises a repeating structure comprising the hardened sub-layer and the overlying or underlying low-k dielectric sub-layer.

12. The device as claimed in claim 10, wherein the hardness of the low-k dielectric sub-layers is between about 0.1 and about 49 GPa while that of the hardened sub-layer is between about 0.5 and about 50 GPa.

13. The device as claimed in claim 11, wherein total thickness of the hardened sub-layers is between 5 to 10% of a thickness of the low-k dielectric layer.

14. The device as claimed in claim 11, wherein a ratio of counts of the low-k dielectric sub-layers to the hardened sub-layers is greater than 1.

15. The device as claimed in claim 10, wherein the low-k dielectric sub-layer comprises carbon.

16. The device as claimed in claim 10, wherein the low-k dielectric sub-layer is Black-diamond, SILK, CORAL, DEMS (diethoxymethylsilane), 3MS (trimethylsilane), or a combination thereof.

17. The device as claimed in claim 10, wherein the hardened sub-layer is the low-k dielectric sub-layer bombarded by hydrogen plasma or inert gas plasma.

18. The device as claimed in claim 17, wherein the inert gas comprises helium, argon, or a combination thereof.

19. A method for fabricating a semiconductor device, comprising:
providing a substrate comprising an etch stop layer on a surface;
forming a first low-k dielectric sub-layer overlying the etch stop layer;
forming a hardened sub-layer overlying the first low-k dielectric sub-layer utilizing bombardment of a surface of the first low-k dielectric sub-layer utilizing inert gas plasma;
forming an uppermost low-k dielectric sub-layer overlying the hardened sub-layer utilizing CVD, thereby forming a low-k dielectric layer comprising the uppermost low-k dielectric sub-layer and the repeating structure; and
embedding a conductive material in the low-k dielectric layer and etch stop layer, the conductive material electrically connecting the substrate.

20. The method as claimed in claim 19, further comprising repeating formation of the first low-k dielectric sub-layer and the overlying hardened sub-layer hardened sub-layer prior to forming the uppermost low-k dielectric sub-layer.

21. The method as claimed in claim 19, wherein the hardened sub-layer is between 5 and 10% as thick as the low-k dielectric layer.

22. The method as claimed in claim 20, wherein total thickness of the hardened sub-layers is between 5 to 10% of a thickness of the low-k dielectric layer.

23. The method as claimed in claim 19, wherein the low-k dielectric sub-layer comprises carbon.

24. The method as claimed in claim 19, wherein the low-k dielectric sub-layer is Black-diamond, SILK, CORAL, DEMS (diethoxymethylsilane), 3MS (trimethylsilane), or a combination thereof.

25. The method as claimed in claim 19, wherein the inert gas comprises helium, argon, or a combination thereof.
